(19) United States
(12) Patent Application Publication
(10) Pub. No.: US 2023/0102044 A1
(43) Pub. Date: Mar. 30, 2023

(54) Bulk acoustic wave resonator and bulk acoustic wave filter

(71) Applicant: Wuhan MEMSonics Technologies Co.,Ltd., Wuhan (CN)

(72) Inventors: Bowoon SOON, Singapore (SG); Yao CAI, Wuhan (CN); Jian WANG, Singapore (SG); Kunli ZHAO, Wuhan (CN); Junwu ZHAO, Wuhan (CN); Yaping ZHOU, Wuhan (CN); Chao GAO, Wuhan (CN); Chengliang SUN, Wuhan (CN)

(21) Appl. No.: 17/949,254

(22) Filed: Sep. 21, 2022

(30) Foreign Application Priority Data
Sep. 23, 2021 (CN) 202111116758.8

(51) Int. Cl. H03H 9/02; H03H 3/02

(52) U.S. Cl. CPC H03H 9/02015; H03H 3/02; H03H 2003/023

(57) ABSTRACT

This present disclosure provides a bulk acoustic wave resonator and a bulk acoustic wave filter, and relates to the technical field of filters. A substrate and a piezoelectric stack structure arranged on the substrate are included. The piezoelectric stack structure includes a bottom electrode, a piezoelectric material layer and a top electrode which are sequentially stacked, and an outline of an orthographic projection of the top electrode on the substrate includes at least one Bezier curve of order greater than or equal to 2. Accordingly, a length of a transverse propagation path of transverse acoustic waves can be increased, thereby increasing losses of the transverse acoustic waves during propagation, and reducing influences of the transverse acoustic waves on a transverse parasitic mode caused by the bulk acoustic wave resonator, and namely, an effect of restraining the transverse parasitic mode is improved by the bulk acoustic wave resonator, thereby improving performance of the bulk acoustic wave filter.

### CROSS-REFERENCE TO RELATED APPLICATION

This present disclosure claims the priority to Chinese patent application No. 202111116758.8, entitled “BULK ACOUSTIC WAVE RESONATOR AND BULK ACOUSTIC WAVE FILTER”, and filed on Sep. 23, 2021 in China, and the contents of which are hereby incorporated by reference in its entirety.

### TECHNICAL FIELD

The present disclosure relates to the technical field of filters, in particular to a bulk acoustic wave resonator and a bulk acoustic wave filter.

### BACKGROUND

A radio-frequency filter plays a crucial role in a radio frequency front-end module, and especially in high-frequency communication, a filter which is based on a bulk acoustic wave resonator technology plays an important role because of its excellent performance. The bulk acoustic wave resonator has characters of high resonant frequency, Complementary Metal-Oxide-Semiconductor (CMOS) process compatibility, high-quality factors, low losses, a low temperature coefficient, high power carrying capacity, etc., thereby gradually replacing a surface acoustic wave resonator to become market mainstream.

The bulk acoustic wave resonator can be divided into an air gap type, a back-etch type, a solid fabrication type, etc., and an ideal working principle includes: radio frequency electric signals are applied to a top electrode and a bottom electrode, vibration in a longitudinal mode is generated by a piezoelectric effect of piezoelectric materials, accordingly, longitudinally-propagated acoustic signals are generated in a sandwich structure consisting of the top electrode, the bottom electrode and the piezoelectric materials, the acoustic signals oscillate in the sandwich structure and then the acoustic signals are converted into electric signals through the piezoelectric effect to be output, and only radio frequency signals matched with the piezoelectric materials in resonant frequency can be transmitted through the bulk acoustic wave resonator, thereby achieving a filtering function. The radio frequency signals are applied to the top electrode and the bottom electrode of the sandwich structure of the bulk acoustic wave resonator, the resonator longitudinally vibrates only in a thickness direction, which is the most ideal situation, but due to influences from a shear piezoelectric effect of the piezoelectric materials, defects possibly existing in the prepared piezoelectric materials, incomplete C-axis orientation and other factors, the resonator transversely vibrates while longitudinally vibrating, which brings a transverse parasitic mode, thereby influencing performance of the resonator.

A pentagon electrode is designed in the prior art so as to reduce influences of transverse propagation of acoustic waves on the parasitic mode. But which an acoustic wave transverse propagation restraining effect in the pentagon electrode is weak.

### SUMMARY

This present disclosure aims to provide a bulk acoustic wave resonator and a bulk acoustic wave filter for overcoming defects in the prior art and with a desirable restraining effect on transverse propagation of acoustic waves.

In order to achieve the above purpose, the embodiment of this present disclosure adopts following technical solutions:

on one aspect of the embodiment of this present disclosure, a bulk acoustic wave resonator is provided and includes a substrate and a piezoelectric stack structure arranged on the substrate, the piezoelectric stack structure includes a bottom electrode, a piezoelectric material layer and a top electrode which are sequentially stacked, and an outline of an orthographic projection of the top electrode on the substrate includes at least one Bezier curve of order greater than or equal to 2.

Optionally, the outline may be formed through sequential end-to-end connection of a plurality of Bezier curves of order greater than or equal to 2.

Optionally, the outline may be formed through end-to-end connection of a Bezier curve of order greater than or equal to 3.

Optionally, the outline may be formed through sequential end-to-end connection of at least one Bezier curve of order greater than or equal to 2 and at least one linear segment.

Optionally, at least one Bezier curve with the order greater than or equal to 2 and at least one linear segment are alternately connected.

Optionally, the outline of an orthographic projection of a top electrode on a substrate is the same in shape with an outline of an orthographic projection of the bottom electrode on the substrate, an outline area of the top electrode is less than an outline area of the bottom electrode, and a distance from the outline of the top electrode to the outline of the bottom electrode is 2-5 microns.

Optionally, a cavity is further arranged in one side, close to the piezoelectric stack structure, of the substrate, and the piezoelectric stack structure is located above the cavity; or, a high-low-acoustic-resistance stack is further arranged between the substrate and the piezoelectric stack structure.

Optionally, wherein material of the piezoelectric layer is one of AIN, ScAIN, ZnO, PZT, LiNbO₃ and LiTaO₃.

Optionally, wherein material of the piezoelectric layer is one of AIN, ScAIN, ZnO, PZT, LiNbO₃ and LiTaO₃.

According to the other aspect of the embodiment of this present disclosure, a bulk acoustic wave filter is provided and includes a plurality of any kind of above bulk acoustic wave resonators, where every two adjacent bulk acoustic wave resonators are connected in series or in parallel.

Optionally, one end of each serially connected bulk acoustic wave resonator is connected to a first signal end, the other end of the serially connected bulk acoustic wave resonator is connected to a second signal end; one end of each bulk acoustic wave resonator connected in parallel is connected to the serially connected bulk acoustic wave resonator, and the other end of the bulk acoustic wave resonator connected in parallel is connected to a grounding end.

The present disclosure has such beneficial effects:

The present disclosure provides the bulk acoustic wave resonator and the bulk acoustic wave filter, the substrate and the piezoelectric stack structure arranged on the substrate are included, the piezoelectric stack structure includes the bottom electrode, the piezoelectric material layer and the top electrode which are sequentially stacked, and the outline of the orthographic projection of the top electrode on the substrate includes at least one Bezier curve of order greater than or equal to 2. Accordingly, a length of a transverse propagation path of transverse acoustic waves can be increased, thereby increasing losses of the transverse acoustic waves in a propagation process, and reducing influences of the transverse acoustic waves on a transverse parasitic mode caused by the bulk acoustic wave resonator, and namely, an effect of restraining the transverse parasitic mode is improved by the bulk acoustic wave resonator so as to improve performance of the bulk acoustic wave filter.

### BRIEF DESCRIPTION OF THE DRAWINGS

In order to describe technical solutions in the embodiments of this present disclosure more clearly, the drawings required to be used in the embodiments will be simply introduced below, it is to be understood that the following drawings only show some embodiments of this present disclosure, which cannot be regarded as limitation on a scope, and ordinary persons skilled in the art can further obtain other related drawings according to the drawings without creative work.

FIG. 1 is a first shape schematic diagram of a top electrode of an existing bulk acoustic wave resonator;

FIG. 2 is a second shape schematic diagram of a top electrode of an existing bulk acoustic wave resonator;

FIG. 3 is an impedance simulation curve chart of the bulk acoustic wave resonator in FIG. 2;

FIG. 4 is a first shape schematic diagram of a top electrode of a bulk acoustic wave resonator provided in an embodiment of this present disclosure;

FIG. 5 is a second shape schematic diagram of a top electrode of a bulk acoustic wave resonator provided in an embodiment of this present disclosure;

FIG. 6 is a third shape schematic diagram of a top electrode of a bulk acoustic wave resonator provided in an embodiment of this present disclosure;

FIG. 7 is a fourth shape schematic diagram of a top electrode of a bulk acoustic wave resonator provided in an embodiment of this present disclosure;

FIG. 8 is a fifth shape schematic diagram of a top electrode of a bulk acoustic wave resonator provided in an embodiment of this present disclosure;

FIG. 9 is a sixth shape schematic diagram of a top electrode of a bulk acoustic wave resonator provided in an embodiment of this present disclosure;

FIG. 10 is a seventh shape schematic diagram of a top electrode of a bulk acoustic wave resonator provided in an embodiment of this present disclosure;

FIG. 11 is an eighth shape schematic diagram of a top electrode of a bulk acoustic wave resonator provided in an embodiment of this present disclosure;

FIG. 12 is a ninth shape schematic diagram of a top electrode of a bulk acoustic wave resonator provided in an embodiment of this present disclosure;

FIG. 13 is a tenth shape schematic diagram of a top electrode of a bulk acoustic wave resonator provided in an embodiment of this present disclosure;

FIG. 14 is a circuit connection schematic diagram of a bulk acoustic wave resonator provided in an embodiment of this present disclosure;

FIG. 15 is an eleventh shape schematic diagram of a top electrode of a bulk acoustic wave resonator provided in an embodiment of this present disclosure;

FIG. 16 is an impedance simulation schematic diagram of the bulk acoustic wave resonator in FIG. 15;

FIG. 17 is a twelfth shape schematic diagram of a top electrode of a bulk acoustic wave resonator provided in an embodiment of this present disclosure;

FIG. 18 is an impedance simulation schematic diagram of the bulk acoustic wave resonator in FIG. 17;

FIG. 19 is a structural schematic diagram of a bulk acoustic wave resonator provided in an embodiment of this present disclosure;

FIG. 20 is a test data schematic diagram of a device in the embodiment shown in FIG. 19;

FIG. 21 is a propagation schematic diagram of transverse acoustic waves and longitudinal acoustic waves provided in an embodiment of this present disclosure;

FIG. 22 is prediction about mass point motion trajectories of different shapes provided in an embodiment of this present disclosure, where (a) is a rectangle, (b) is an irregular pentagon, and (c) is a Bezier curve;

FIG. 23 is a current direction schematic diagram provided in an embodiment of this present disclosure, where (a), (b) and (c) are different electrode shapes, and (d) is a sectional view of (a), (b) and (c); and

FIG. 24 is a schematic diagram of a bulk acoustic wave resonator provided in an embodiment of this present disclosure.

Icons: 10-outline of top electrode of existing bulk acoustic wave resonator; 11-transverse propagation path of existing bulk acoustic wave resonator; 100-outline; 101-transverse propagation path; 301-second Bezier curve; 302-second linear segment; 303-third linear segment; 304-third Bezier curve; 305-fourth linear segment; 306-fourth Bezier curve; 401-first Bezier curve; 402-first linear segment; 403-fifth linear segment; 404-sixth linear segment; 405-fifth Bezier curve; 406-sixth Bezier curve; 407-seventh linear segment; 408-ninth linear segment; 409-seventh Bezier curve; 410-ninth Bezier curve; 411-eighth linear segment; 412-eighth Bezier curve; 501-top electrode; 502-piezoelectric material layer; 503-bottom electrode; 504-first signal end; 505-second signal end; 803-series bulk acoustic wave resonator; 804-parallel bulk acoustic wave resonator; and 802-grounding end.

### DETAILED DESCRIPTION OF THE EMBODIMENTS

To make purposes, technical solutions and advantages of embodiments of this present disclosure more clearly, the technical solutions in the embodiments of this present disclosure are clearly and integrally described in combination with drawings in the embodiments of this present disclosure as below, and it is apparent that the described embodiments are only a part rather all of embodiments. Assemblies, described and shown in the drawings herein, in the embodiments of this present disclosure may be generally arranged and designed according to different configurations.

It is to be understood that terms such as “first” and “second” may be used for describing various elements in this present disclosure but cannot limit the elements. The terms are only used for distinguishing one element from another element. For instance, a first element may be called as a second element without departing from a scope of the present disclosure, and similarly, the second element may be called as the first element. A term “and/or” used in this present disclosure includes any one or more and all combinations of associated listed items.

It is to be understood that when one element (such as a layer, an area or a substrate) is “arranged on another element” or “extends to another element”, the element may be directly arranged on another element or directly extend to another element, or a middle element may exist. On the contrary, when one element is “directly arranged on another element” or “directly extends to another element”, a middle element does not exist. Similarly, it is to be understood that when one element (such as a layer, an area or a substrate) is “arranged above another element” or “extends above another element”, the element may be directly arranged above another element or directly extend above another element, or a middle element may exist. On the contrary, when one element is “directly arranged above another element” or “directly extends above another element”, a middle element does not exist. It is to be understood that when one element is “ connected” or “coupled” to another element, the element may be directly connected or coupled to another element, or a middle element may exist. On the contrary, when one element is “directly connected” or “directly coupled” to another element, a middle element does not exist.

Except additional definition, all terms (including technological and scientific terms) used in this present disclosure have the same meaning usually understood by ordinary persons skilled in the art of the present disclosure. It is to be understood that the terms used in this present disclosure are explained to be consistent to those in the Description and related fields in meaning instead of being explained with ideal or too formal meaning, except clear definition in this present disclosure.

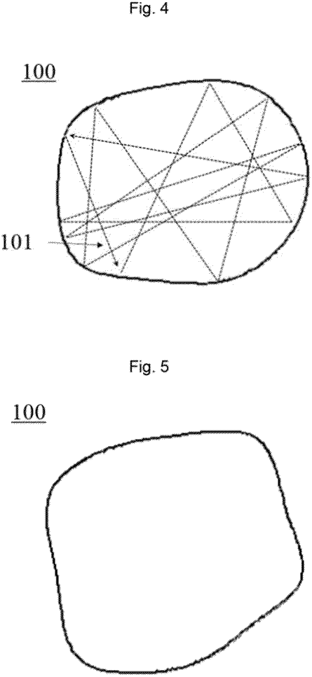

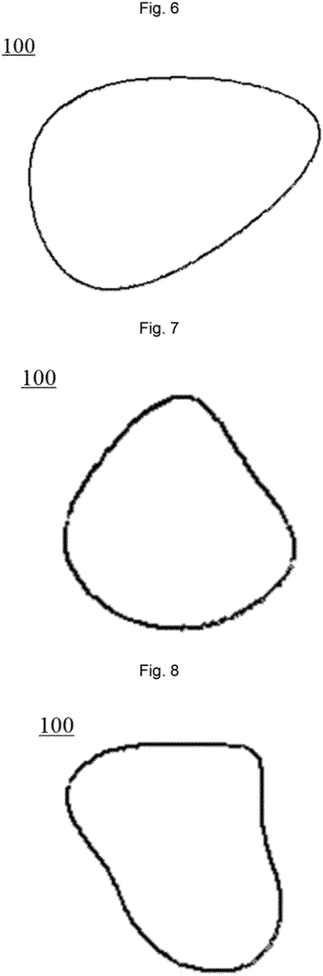

On one aspect of the embodiment of this present disclosure, a bulk acoustic wave resonator is provided, and as shown in FIG. 4-FIG. 18, includes a substrate and a piezoelectric stack structure arranged on the substrate. The piezoelectric stack structure includes a bottom electrode 503 arranged on the substrate, a piezoelectric material layer 502 arranged on the bottom electrode 503 and a top electrode 501 arranged on the piezoelectric material layer 502, and an outline of an orthographic projection of the top electrode 501 on the substrate includes at least one Bezier curve of order greater than or equal to 2.ln some implementation modes, process flow of machining the top electrode 501 of this present disclosure includes: firstly, growing of a layer of top electrode material on the piezoelectric material layer 501, spin coating of photoresist and exposure development. Compared with preparation of an irregular pentagon or rectangle top electrode, when the top electrode 501 of this present disclosure is prepared, a heating flux process needs to be performed after development is finished, so that photoresist on an edge of a pattern is smoother and tidier, accordingly, it is guaranteed that an edge curve of the top electrode 501 is smooth when the top electrode 501 is patterned, a better Bezier curve effect is achieved, and influences from the parasitic mode are weakened.

In some implementation modes, the substrate may be a silicon substrate, a sapphire substrate, etc. In some implementation modes, the piezoelectric material layer 502 may be made of one of AIN, ScAIN, ZnO, PZT, LiNbO₃ and LiTaO₃.During specific selection, reasonable selection may be performed according to actual needs and is not limited in the embodiment.

As shown in FIG. 4, an outline 100 of an orthographic projection of a top electrode 501 on a substrate includes at least one Bezier curve of order greater than or equal to 2, thereby improving irregularity of an edge of the outline 100 and smoothening the edge of the outline 100. No right angle is formed in the outline 100 so that a length of a transverse propagation path 101 of transverse acoustic waves in the top electrode 501 can be increased, thereby increasing losses of the transverse acoustic waves in the propagation process, and then reducing influences of the transverse acoustic waves on a transverse parasitic mode caused by a bulk acoustic wave resonator, and namely, an effect of restraining the transverse parasitic mode is improved by the bulk acoustic wave resonator so as to improve performance of the bulk acoustic wave resonator.

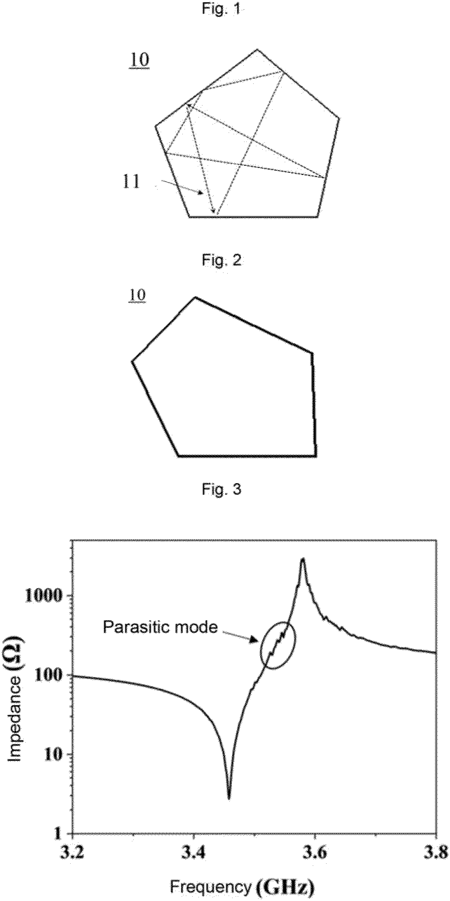

FIG. 1 shows a shape being pentagon of an outline 10 of a top electrode of an existing bulk acoustic wave resonator, and it can be seen according to FIG. 1 that after acoustic waves enter the top electrode 501, a transverse propagation path 11 of the existing bulk acoustic wave resonator is short. As shown in FIG. 4, the top electrode 501 of this present disclosure has the Bezier curve with the order greater than or equal to 2, and it can be seen according to FIG. 4 that after the acoustic waves enter the top electrode 501, the transverse propagation path 101 is long, thereby effectively increasing losses of the acoustic waves during transverse propagation.

The Bezier curve may be controlled by n points, and when given points are P₀, P₁...Pₙ, a general parameter formula of the Bezier curve is:

$$B \left(t\right) = {\sum }_{i = 0}^{n} \left({}_{i}^{n}\right) {P}_{i} {\left(1 - t\right)}^{n - i} {t}^{i}$$

$$\left({}_{i}^{n}\right) = \frac{n !}{i ! \left(n - 1\right) !}$$

Where, t∈[0,1], a point Pᵢ is a control point of the Bezier curve, a Bezier polygon is formed by connecting the control points of the linear Bezier curve, and a shape of the Bezier curve and a shape of the Bezier polygon may be reasonably designed by controlling positions of the given points P₀, P₁...Pₙ from P₀ to Pₙ.n is a control number of the order of the Bezier curve, when n is 1, the control points are p₀ and p₁, and the order of the Bezier curve is 1, namely a line segment; and when n is greater than or equal to 3, the control points are P₀, P₁...Pₙ, and if p₀ coincides with Pₙ, the Bezier curve may form an end-to-end closed curve.

Optionally, as shown in FIG. 4, the shape of the outline 100 of the top electrode 501 is formed through end-to-end connection of the Bezier curve with the order greater than or equal to 3, so that a start point and an end point of the Bezier curve coincide with each other so as to form the shape, defined by the Bezier curve with the order greater than or equal to 3, of the top electrode 501 shown in FIG. 4, and accordingly, the outline 100 of the top electrode 501 can be smoother and more irregular, thereby further increasing the length of the transverse propagation path of the acoustic waves, increasing losses in the propagation process, and reducing influences from the transverse parasitic mode.

FIG. 5-FIG. 8 further show four shapes of outlines 100 of top electrodes 501, the outline 100 in each shape is a closed Bezier curve of order greater than or equal to 3, and thus when acoustic waves transversely propagate in the four top electrodes 501, a transverse propagation path of the acoustic waves is long.

Optionally, an outline 100 of a top electrode 501 may be formed through sequential end-to-end connection of a plurality of Bezier curves of order greater than or equal to 2, accordingly, all parts of the outline 100 may be irregular and smooth curves, and therefore after acoustic waves enter the top electrode 501, a transverse propagation path 101 is long, thereby effectively increasing losses of the acoustic waves during transverse propagation.

Optionally, an outline 100 of a top electrode 501 may be formed through sequential end-to-end connection of at least one Bezier curve of order greater than or equal to 2 and at least one linear segment, for instance:

in an implementation mode, an outline 100 of a top electrode 501 shown in FIG. 11 is a closed figure formed through sequential end-to-end connection of a first linear segment 402 and a first Bezier curve 401 of order greater than or equal to 2.

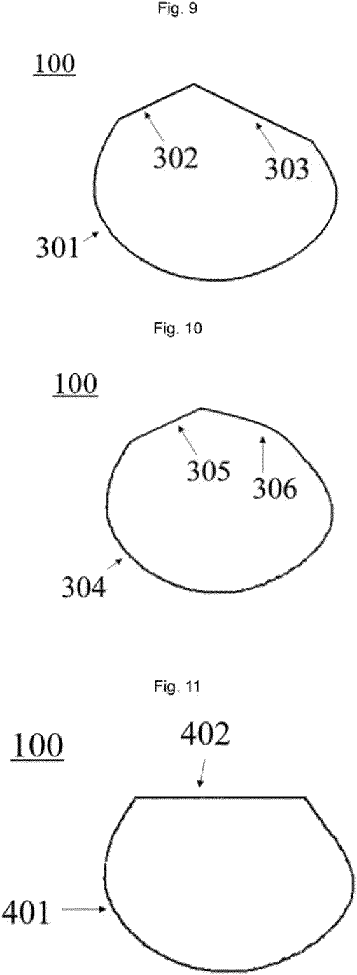

In some implementation modes, an outline 100 of a top electrode 501 shown in FIG. 9 is a closed figure formed through sequential end-to-end connection of a second linear segment 302, a third linear segment 303 and a second Bezier curve 301 of order greater than or equal to 2.

In some implementation modes, an outline 100 of a top electrode 501 shown in FIG. 10 is a closed figure formed through sequential end-to-end connection of a fourth linear segment 305, a third Bezier curve 304 of order greater than or equal to 2 and a fourth Bezier curve 306 of order greater than or equal to 2 .

Optionally, at least one Bezier curve of order greater than or equal to 2 and at least one linear segment are alternately connected, for instance:

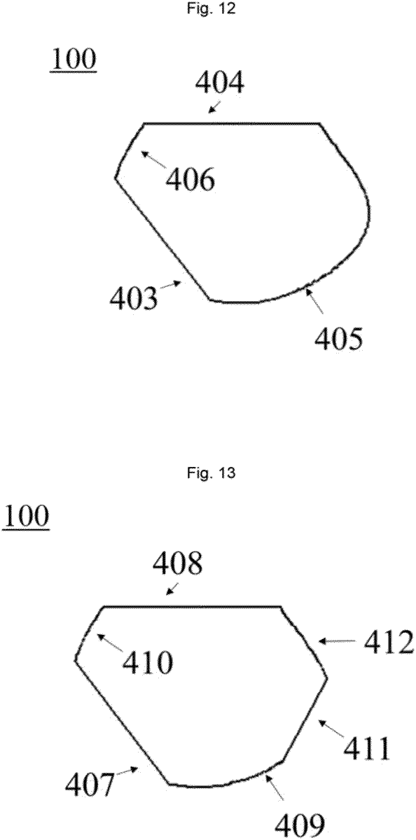

in some implementation modes, an outline 100 of a top electrode 501 shown in FIG. 12 is a closed figure formed through sequential end-to-end connection of a fifth linear segment 403, a fifth Bezier curve 405 of order greater than or equal to 2, a sixth linear segment 404 and a sixth Bezier curve 406 of order greater than or equal to 2.

In some implementation modes, an outline 100 of a top electrode 501 shown in FIG. 13 is a closed figure formed through sequential end-to-end connection of a seventh linear segment 407, a seventh Bezier curve 409 of order greater than or equal to 2, an eighth linear segment 411, an eighth Bezier curve 412 of order greater than or equal to 2, a ninth linear segment 408 and a ninth Bezier curve 410 of order greater than or equal to 2.

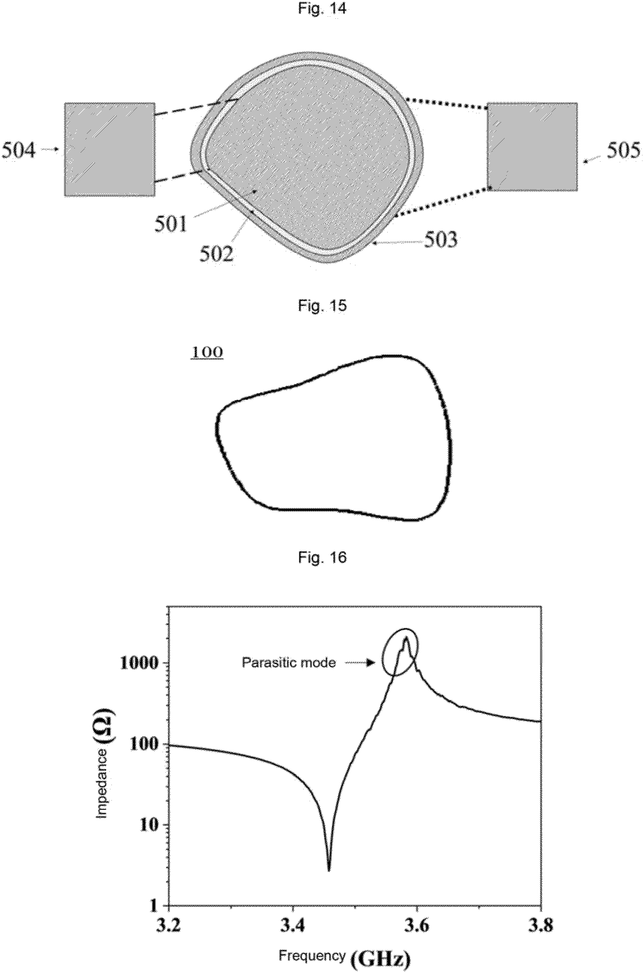

Optionally, as shown in FIG. 14, when a top electrode 501, a piezoelectric material layer 502 and a bottom electrode 503 have orthographic projections on a substrate, an outline 100 of the top electrode 501 may be the same in shape with an outline 100 of the bottom electrode 503 and an outline 100 of the piezoelectric material layer 502, thereby further improving an effect of restraining a transverse parasitic mode by a bulk acoustic wave resonator and then improving device performance.

As shown in FIG. 14, an area of the outline 100 of the top electrode 501 may be less than that of the piezoelectric material layer 502, the area of the outline 100 of the piezoelectric material layer 502 is less than that of the bottom electrode 503, namely, the piezoelectric material layer 502 may be externally expanded relative to the top electrode 501, and the bottom electrode 503 may be externally expanded relative to the piezoelectric material layer 502. In some implementation modes, a distance from an outline 100 of a top electrode 501 to an outline 100 of a bottom electrode 503 ranges from 2 microns to 5 microns, such as 3 microns and 4 microns.

FIG. 2 shows a pentagon top electrode 501, with an electrode area being 4300 square microns, of an existing bulk acoustic wave resonator, an impedance curve graph shown in FIG. 3 can be obtained through simulation, and it can be seen from FIG. 3 that the bulk acoustic wave resonator has an obvious transverse parasitic mode.

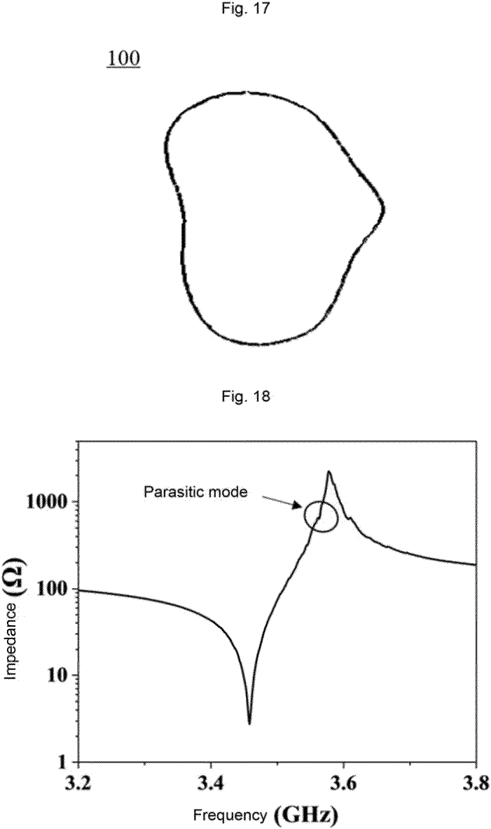

Optionally, FIG. 15 and FIG. 17 show outlines 100 of two shapes of top electrodes 501, the outline 100 in each shape is a closed Bezier curve of order greater than or equal to 3, an area of each shape of top electrode 501 may be 4300 square microns, impedance curve graphs shown in FIG. 16 and FIG. 18 can be obtained through simulation, and it can be seen from FIG. 16 and FIG. 18 that a transverse parasitic mode in impedance curves is obviously reduced.

In some implementation modes, a cavity is formed in one side, close to a piezoelectric stack structure, of a substrate, the piezoelectric stack structure is located above the cavity, namely, a groove with the cavity is formed in an upper surface of the substrate through an etching process, and then, the piezoelectric stack structure is arranged on the substrate and at least covers an opening of the groove, thereby improving performance of a bulk acoustic wave resonator.

In some implementation modes, a high-low-acoustic-resistance stack is further arranged between a substrate and a piezoelectric stack structure, and namely, alternate layers of a high-acoustic-resistance material layer and a low-acoustic-resistance material layer are formed on an upper surface of the substrate in an alternate lamination manner, thereby improving performance of a bulk acoustic wave resonator.

Optionally, as shown in FIG. 14, when a bulk acoustic wave resonator performs circuit connection, a top electrode 501 of the bulk acoustic wave resonator may be connected to a first signal end 504, and a bottom electrode 503 is connected to a second signal end 505.

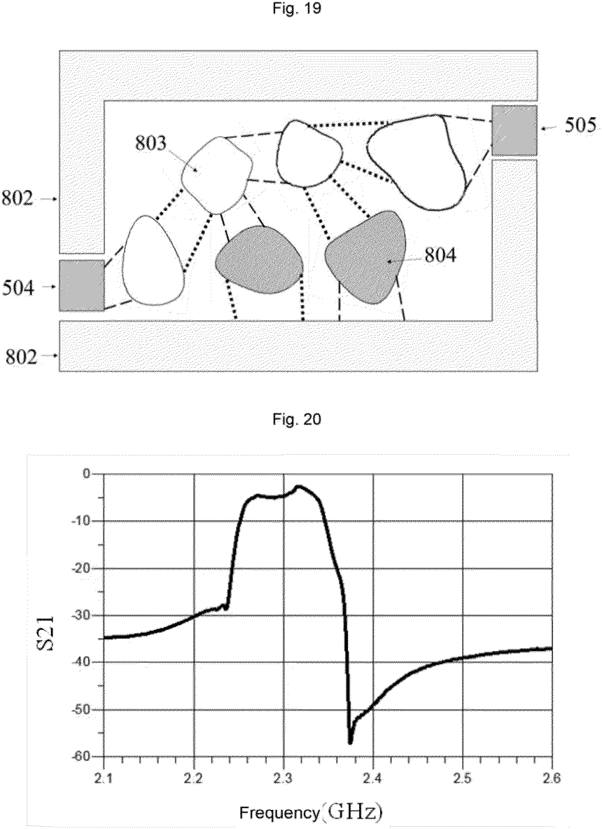

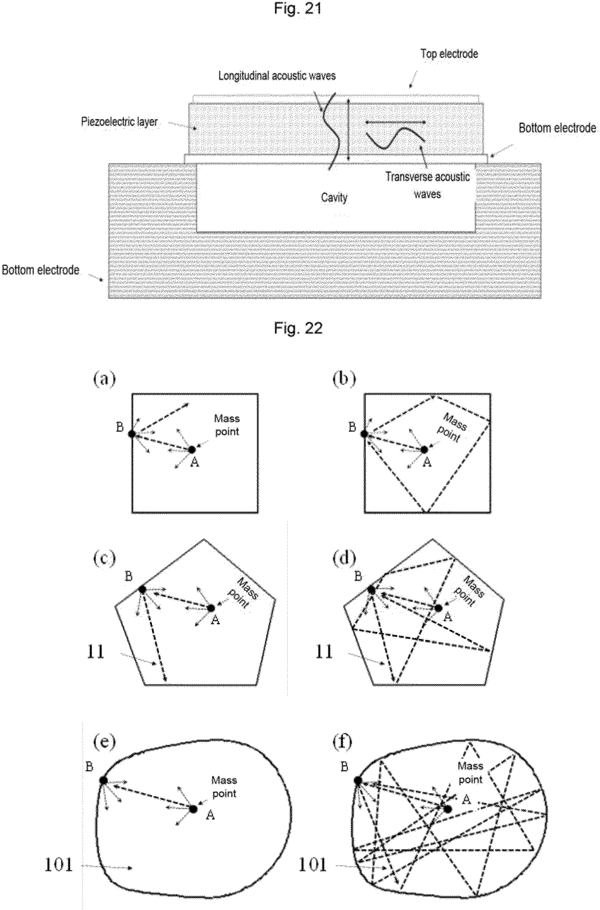

On the other aspect of the embodiment of this present disclosure, a bulk acoustic wave filter is provided, and as shown in FIG. 19, includes a plurality of any kind of bulk acoustic wave resonators, every two adjacent bulk acoustic wave resonators may be connected in series or in parallel, a top electrode 501 of each bulk acoustic wave resonator includes at least one Bezier curve of order greater than or equal to 2, and therefore a length of a transverse propagation path 101 of transverse acoustic waves can be increased, thereby increasing losses of the transverse acoustic waves in a propagation process, and reducing influences of the transverse acoustic waves on a transverse parasitic mode caused by the bulk acoustic wave resonators, and namely, an effect of restraining the transverse parasitic mode is improved by the bulk acoustic wave resonators so as to improve performance of the bulk acoustic wave filter.

As shown in FIG. 19, a series bulk acoustic wave resonator 803 circuit and two bulk acoustic wave resonator 804 circuits connected to the series bulk acoustic wave resonator 803 circuit in parallel are included, where, one end of each series bulk acoustic wave resonator 803 is connected to a first signal end 504, the other end of each series bulk acoustic wave resonator 803 is connected to a second signal end 505, one end of each parallel bulk acoustic wave resonator 804 is connected to the corresponding series bulk acoustic wave resonator 803, and the other end of each parallel bulk acoustic wave resonator 804 is connected to a grounding end 802.Each bulk acoustic wave resonator 803 is in a Bezier curve shape, and when the resonators are utilized for being combined to construct the filter, the bulk acoustic wave resonators 803 in the Bezier curve shape may provide more selectivity for device arrangement, thereby reducing a size of the filter and arranging the resonators more tightly.

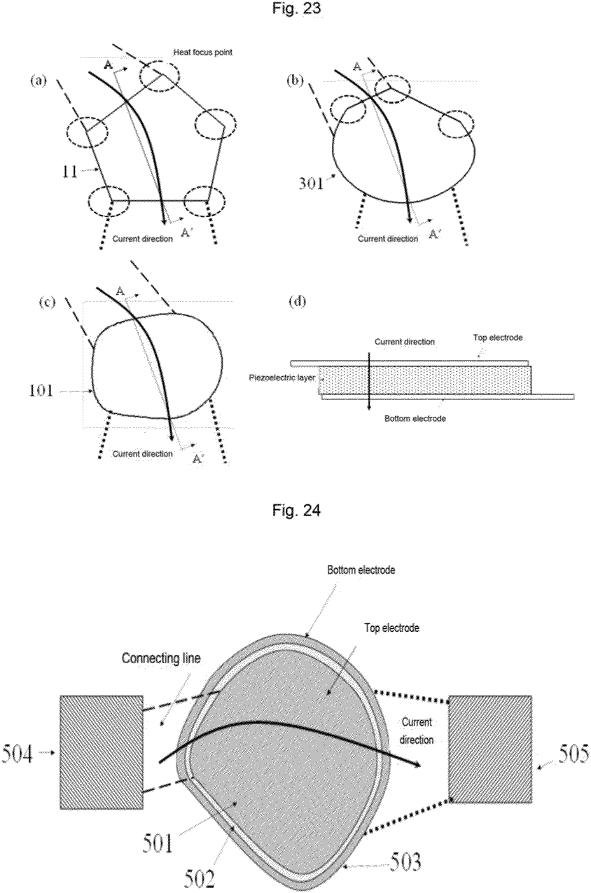

During actual work, radio frequency signals are transmitted through top electrodes 501 and bottom electrodes 503 in the filter. Along with transmission of electric signals in the resonators, the resonators generate resonance due to a piezoelectric effect and constantly generate heat. As shown in FIG. 23, sharp corners in an irregular pentagon in FIG. 23(a) and a Bezier curve and line segment combined shape in FIG. 23(b) are all current focus points, heat focus points and stress focus points. Along with long-time work of resonators, heat is constantly gathered, and devices firstly break at the sharp corners and then lose efficacy. Each bulk acoustic wave resonator 803 presented and designed by this present disclosure is in a Bezier curve shape, and an outline of an orthographic projection of each top electrode 501 on a corresponding substrate includes at least one Bezier curve of order greater than or equal to 2 so that the sharp corners can be effectively reduced, thereby avoiding excessive concentration of current, heat and stress as much as possible, enabling the resonators to work more stably, and prolonging service life.

Machining is performed according to an embodiment structure shown in FIG. 19, and an obtained transmission curve of the filter is shown in FIG. 20.The transmission curve is smooth in passband and less in ripple, thereby proving that the filter design shown in FIG. 19 can effectively restrain the transverse parasitic mode.

In a work process of the bulk acoustic wave resonators, acoustic signals oscillate in sandwich structures. As shown in FIG. 22, the bulk acoustic wave resonators only longitudinally vibrate in a thickness direction to generate longitudinal acoustic waves, which is a most ideal situation. But due to influences from a shear piezoelectric effect of piezoelectric materials, defects possibly existing in the prepared piezoelectric materials, incomplete C-axis orientation and other factors, the resonators transversely vibrate while longitudinally vibrating, which causes transverse acoustic wave propagation, thereby influencing performance of the resonators.

A main purpose of this present disclosure is to design the bulk acoustic wave resonator shape into the Bezier curve shape, thereby increasing the length of the transverse propagation path of the transverse acoustic waves, increasing losses of the transverse acoustic waves in the propagation process, and reducing influences of the transverse acoustic waves on the transverse parasitic mode caused to the bulk acoustic wave resonators. As shown in FIG. 22, conventional resonator structures are in a rectangle or irregular polygon shape. This present disclosure utilizes a particle motion trajectory for analyzing propagation of the transverse acoustic waves and adopts a Monte Carlo algorithm to predict the particle motion trajectory. For the rectangle or irregular-pentagon resonator, a mass point A randomly moves on a rectangle or irregular pentagon, and a plurality of random motion paths exist. Amusing that the mass point A moves to a mass point B, one possible propagation trajectory of the mass point A on each of the rectangle and the irregular pentagon can be obtained through Monte Carlo prediction, as shown in FIG. 22(a), FIG. 22(b),FIG. 22(c) and FIG. 22(d).

The resonator presented and designed by this present disclosure is in the Bezier curve shape, and the outline of the orthographic projection of the resonator top electrode 501 on the substrate includes at least one Bezier curve with the order greater than or equal to 2. As shown in FIG. 22(e) and FIG. 22(f), relative to a motion trajectory of the mass point A on each of the rectangle and the irregular pentagon, a motion trajectory of the mass point A in the Bezier curve shape is predicted through a Monte Carlo method, and the more complex the motion path of the mass point A, the longer the propagation path becomes. Thus, when the rectangle, the irregular pentagon and the Bezier curve shape are the same in area and the transverse acoustic waves are propagated in the Bezier curve shape, due to the complex and longer propagation of the transverse acoustic waves, acoustic wave energy is basically consumed in a reflection and propagation process, and generated transverse parasitic mode influences become weak.

As shown in FIG. 24, when the top electrodes 501 and the bottom electrodes 503 in designed resonators and connecting lines are arranged, the bulk acoustic wave resonators 803 designed in the Bezier curve shape may provide a maximum cross section and current direction length ratio under a fixed area, thereby reducing resistance losses of the bulk acoustic wave resonators 803 and improving quality factors of the resonators.

The above embodiments are merely preferable embodiments of this present disclosure and not used for limiting this present disclosure, and this present disclosure can be variously modified and changed for persons skilled in the art. Any modification, equivalent replacement, improvement, etc. made within the spirit and the principle of this present disclosure shall fall within the scope of protection of this present disclosure.

1. A bulk acoustic wave resonator, comprising a substrate and a piezoelectric stack structure arranged on the substrate, wherein the piezoelectric stack structure comprises a bottom electrode, a piezoelectric material layer and a top electrode which are sequentially stacked, and an outline of an orthographic projection of the top electrode on the substrate comprises at least one Bezier curve of order greater than or equal to 2.

2. The bulk acoustic wave resonator according to claim 1, wherein the outline is formed through sequential end-to-end connection of a plurality of Bezier curves of order greater than or equal to 2.

3. The bulk acoustic wave resonator according to claim 1, wherein the outline is formed through end-to-end connection of Bezier curves of order greater than or equal to 3.

4. The bulk acoustic wave resonator according to claim 1, wherein the outline is formed through sequential end-to-end connection of at least one Bezier curve of order greater than or equal to 2 and at least one linear segment.

5. The bulk acoustic wave resonator according to claim 4, wherein the at least one Bezier curve of order greater than or equal to 2 and the at least one linear segment are alternately connected.

6. The bulk acoustic wave resonator according to claim 1, wherein the outline of the orthographic projection of the top electrode on the substrate is the same in shape with an outline of an orthographic projection of the bottom electrode on the substrate, an outline area of the top electrode is less than an outline area of the bottom electrode, and a distance from the outline of the top electrode to the outline of the bottom electrode is 2-5 microns.

7. The bulk acoustic wave resonator according to claim 2, wherein the outline of the orthographic projection of the top electrode on the substrate is the same in shape with an outline of an orthographic projection of the bottom electrode on the substrate, an outline area of the top electrode is less than an outline area of the bottom electrode, and a distance from the outline of the top electrode to the outline of the bottom electrode is 2-5 microns.

8. The bulk acoustic wave resonator according to claim 3, wherein the outline of the orthographic projection of the top electrode on the substrate is the same in shape with an outline of an orthographic projection of the bottom electrode on the substrate, an outline area of the top electrode is less than an outline area of the bottom electrode, and a distance from the outline of the top electrode to the outline of the bottom electrode is 2-5 microns.

9. The bulk acoustic wave resonator according to claim 4, wherein the outline of the orthographic projection of the top electrode on the substrate is the same in shape with an outline of an orthographic projection of the bottom electrode on the substrate, an outline area of the top electrode is less than an outline area of the bottom electrode, and a distance from the outline of the top electrode to the outline of the bottom electrode is 2-5 microns.

10. The bulk acoustic wave resonator according to claim 5, wherein the outline of the orthographic projection of the top electrode on the substrate is the same in shape with an outline of an orthographic projection of the bottom electrode on the substrate, an outline area of the top electrode is less than an outline area of the bottom electrode, and a distance from the outline of the top electrode to the outline of the bottom electrode is 2-5 microns.

11. The bulk acoustic wave resonator according to claim 1, wherein a cavity is further arranged in one side, close to the piezoelectric stack structure, of the substrate, and the piezoelectric stack structure is located above the cavity; or, a high-low-acoustic-resistance stack is further arranged between the substrate and the piezoelectric stack structure.

12. The bulk acoustic wave resonator according to claim 1, wherein a cavity is further arranged in one side, close to the piezoelectric stack structure, of the substrate, and the piezoelectric stack structure is located above the cavity; or, a high-low-acoustic-resistance stack is further arranged between the substrate and the piezoelectric stack structure.

13. The bulk acoustic wave resonator according to claim 2, wherein a cavity is further arranged in one side, close to the piezoelectric stack structure, of the substrate, and the piezoelectric stack structure is located above the cavity; or, a high-low-acoustic-resistance stack is further arranged between the substrate and the piezoelectric stack structure.

14. The bulk acoustic wave resonator according to claim 3, wherein a cavity is further arranged in one side, close to the piezoelectric stack structure, of the substrate, and the piezoelectric stack structure is located above the cavity; or, a high-low-acoustic-resistance stack is further arranged between the substrate and the piezoelectric stack structure.

15. The bulk acoustic wave resonator according to claim 4, wherein a cavity is further arranged in one side, close to the piezoelectric stack structure, of the substrate, and the piezoelectric stack structure is located above the cavity; or, a high-low-acoustic-resistance stack is further arranged between the substrate and the piezoelectric stack structure.

16. The bulk acoustic wave resonator according to claim 5, wherein a cavity is further arranged in one side, close to the piezoelectric stack structure, of the substrate, and the piezoelectric stack structure is located above the cavity; or, a high-low-acoustic-resistance stack is further arranged between the substrate and the piezoelectric stack structure.

17. The bulk acoustic wave resonator according to claim 1, wherein material of the piezoelectric layer is one of AIN, ScAIN, ZnO, PZT, LiNbO₃ and LiTaO₃.

18. The bulk acoustic wave resonator according to claim 3, wherein material of the piezoelectric layer is one of AIN, ScAIN, ZnO, PZT, LiNb₃ and LiTaO₃.

19. A bulk acoustic wave filter, comprising a plurality of bulk acoustic wave resonators according to claim 1, wherein every two adjacent bulk acoustic wave resonators are connected in series or in parallel.

20. The bulk acoustic wave filter according to claim 19, wherein one end of each serially connected bulk acoustic wave resonator is connected to a first signal end, the other end of the serially connected bulk acoustic wave resonator is connected to a second signal end; one end of each bulk acoustic wave resonator connected in parallel is connected to the serially connected bulk acoustic wave resonator, and the other end of the bulk acoustic wave resonator connected in parallel is connected to a grounding end.
